(19) United States
(12) Patent Application Publication
(10) Pub. No.: US 2025/0165031 A1
(43) Pub. Date: May 22, 2025

(54) METHOD FOR ATTACHING DISPLAY COVER AND ATTACHING DEVICE

(71) Applicant: WUHAN CHINA STAR OPTOELECTRONICS SEMICONDUCTOR DISPLAY TECHNOLOGY CO., LTD., Wuhan, Hubie (CN)

(72) Inventors: Bin Zou, Wuhan, Hubei (CN); Liang Sun, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 17/622,862

(22) PCT Filed: Dec. 22, 2021
(86) PCT No.: PCT/CN2021/140285

§ 371 Date: Oct. 14, 2024

(30) Foreign Application Priority Data
Dec. 10, 2021 (CN) 202111506279.7

(51) Int. Cl. G06F 1/16; H10K 77/10; H10K 102/00

(52) U.S. Cl. CPC G06F 1/1652; G06F 1/1656; H10K 77/111; H10K 2102/311

(57) ABSTRACT

A method and device for attaching a display cover are provided. In an attaching method, a display panel is fixed to a sealing mechanism, and a cover is fixed to a bottom of an accommodating cavity of a housing. By filling a sealed space of the sealing mechanism with a pressurized gas, while a stretching mechanism pushes the display panel to deform, the display panel and the cover are bonded together under an action of the stretching mechanism and the pressurized gas. This alleviates an issue of a limited molding process in realization of three-dimensional curved surface of current flexible OLED and flexible micro-LED displays.

### TECHNICAL FIELD

The present application relates to the field of display technologies, and more particularly to a method for attaching a display cover and an attaching device.

### BACKGROUND

Flexible organic light emitting diode (OLED) displays and flexible micro-LED displays have advantages of active luminescence, large viewing angles, wide color gamut, high brightness, fast response speed, low power consumption, bendable and foldable in structure, and are becoming more and more popular in the market. Utilizing the flexible OLEDs and flexible micro-LED displays can be bent and foldable, it can realize static bending, dynamic bending and reel forms. With a development of display technologies and a diversification of demand for terminal products, requirements for spatial three-dimensional surface display are put forward.

However, because the above-mentioned displays are based on a semiconductor process of thin film transistors, a manufacturing process is also performed in a planar manner. Basic display functions are presented in a flat form. Part of a flexible display panel will be attached to a protective cover in a curved surface along a linear axis, thereby presenting a certain curved shape (such as a hyperboloid or four-curved surface). This curved shape along the linear axis is not a true three-dimensional curved surface. A true three-dimensional curved surface needs to be stretched at least biaxially for a flat film form of the display to form a spatial three-dimensional curved surface.

The three-dimensional curved surface is usually formed by injection molding, extrusion, stamping and other methods to obtain the three-dimensional curved surface shape. However, because there are millions of micron-scale transistors and metal circuits in the flexible display, a tolerance to molding temperature and pressure is limited, and the above-mentioned process cannot be used for molding.

### SUMMARY

### Technical Problem

The present application provides an attaching method for a display cover and an attaching device, so as to alleviate the technical problem that current flexible OLED and flexible micro-LED displays realize three-dimensional curved surface with limited molding process.

### TECHNICAL SOLUTION FOR PROBLEM

### Technical Solution

In order to solve the above problems, the technical solutions provided by this application are as follows:

An embodiment of the present application provides a method for attaching a display cover, wherein a display comprises a display panel and a cover, the display panel and the cover are attached by an attaching device, and the method for attaching the display cover comprises:
fixing the cover to a bottom of an accommodating cavity of the attaching device;
fixing the display panel in a sealing mechanism of the accommodating cavity of the attaching device facing a side of the cover, forming a sealed space by the sealing mechanism, and arranging the display panel and the cover opposite to each other;
filling the sealed space of the sealing mechanism with a pressurized gas, pushing a stretching mechanism movably connected with the sealing mechanism to move to the display panel, and bonding the display panel and the cover under a pushing force of the stretching mechanism and a pressure of the pressurized gas.

In the method for attaching the display cover according to an embodiment of the present application, before filling the sealed space of the sealing mechanism with the pressurized gas, the method for attaching the display cover comprises following steps:
heating the sealed space of the sealing mechanism and the display panel at a preset temperature by a heating mechanism fixed in the sealing mechanism.

In the method for attaching the display cover according to an embodiment of the present application, the preset temperature ranges from 70 degrees Celsius to 150 degrees Celsius.

In the method for attaching the display cover according to an embodiment of the present application, a heating method of the heating mechanism comprises at least one heating method selected from a UV irradiation, an infrared heating, a resistance wire heating, a microcrystalline heating plate heating, and a quartz tube heating.

In the method for attaching the display cover according to an embodiment of the present application, a step of filling the sealed space of the sealing mechanism with the pressurized gas comprises:
filling the pressurized gas into a chamber of the stretching mechanism through a first air inlet of the stretching mechanism located outside the sealing mechanism, and the pressurized gas entering the sealed space of the sealing mechanism through a first air outlet of the stretching mechanism located in the sealing mechanism.

In the method for attaching the display cover according to an embodiment of the present application, a step of filling the sealed space of the sealing mechanism with the pressurized gas comprises:
filling the sealed space of the sealing mechanism with the pressurized gas through a second air inlet on the sealing mechanism.

In the method for attaching the display cover according to an embodiment of the present application, a pressure of the pressurized gas ranges from 0.5 Mpa to 4 Mpa.

In the method for attaching the display cover according to an embodiment of the present application, a step of fixing the display panel at a third opening of the sealing mechanism comprises:
fixing the display panel to a side of the sealing mechanism facing the cover through a clamping member on the sealing mechanism.

In the method for attaching the display cover according to an embodiment of the present application, step of pushing the stretching mechanism to move to the display panel further comprises:
pushing the stretching mechanism to move to the display panel and making a lifting mechanism at the bottom of the accommodating cavity push the cover to move to the display panel.

In the method for attaching the display cover according to an embodiment of the present application, before fixing the display panel in the sealing mechanism of the accommodating cavity of the attaching device facing the side of the cover, the method further comprises:
attaching a protective layer to a side of the display panel;
fixing the display panel on a side of the sealing mechanism facing the cover, and the protective layer facing the sealing mechanism.

In the method for attaching the display cover according to an embodiment of the present application, the method further comprises peeling off the protective layer after bonding the display panel and the cover.

An embodiment of the present application further provides an attaching device, comprising:
a housing formed with an accommodating cavity, wherein a side of the housing has a first opening;
a sealing mechanism disposed in the accommodating cavity and having a second opening and a third opening opposite to the first opening;
a stretching mechanism passing through the first opening and being slidably connected to the sealing mechanism through the second opening.

In the attaching device according to an embodiment of the present application, the attaching device further comprises a heating mechanism fixed in the sealed space of the sealing mechanism.

In the attaching device according to an embodiment of the present application, the stretching mechanism comprises a chamber, a first air inlet on a side of the chamber, and a first air outlet on another side of the chamber, and the chamber passes through the sealed space of the sealing mechanism through the first air outlet.

In the attaching device according to an embodiment of the present application, an end of the stretching mechanism located in the sealed space of the sealing mechanism is a circular arc surface.

In the attaching device according to an embodiment of the present application, the sealing mechanism is provided with a second air inlet, and the second air inlet is located between the second opening and the third opening.

In the attaching device according to an embodiment of the present application, the housing corresponding to the bottom of the accommodating cavity is provided with a second air outlet, and the sealed space of the sealing mechanism is communicated with an outside through the second air outlet.

In the attaching device according to an embodiment of the present application, the attaching device further comprises a clamping member, the clamping member being disposed on an edge of the third opening of the sealing mechanism.

In the attaching device according to an embodiment of the present application, the attaching device further comprises a lifting mechanism disposed at the bottom of the accommodating cavity.

In the attaching device according to an embodiment of the present application, a size of the second opening is less than a size of the third opening.

### BENEFICIAL EFFECTS OF INVENTION

### Beneficial Effects

In the attaching method for the display cover and the attaching device provided in the present application, the display panel is fixed to the sealing mechanism, and the cover is fixed to the bottom of the accommodating cavity of the housing. The heating mechanism is used to heat the display panel, and the pressurized gas is filled into the sealed space of the sealing mechanism. Further, the stretching mechanism pushes the display panel to deform. The display panel and the cover are bonded under the action of the stretching mechanism and the pressurized gas, so that molding and bonding of the display are integrated. This avoids problems such as poor fit and wrinkles caused by a difference in curvature when the display panel and the cover are formed separately. This solves the problem that current flexible OLED and flexible micro-LED displays have limited molding processes for realizing three-dimensional curved surfaces. Further, by controlling timing of an axial pressing of the stretching mechanism and the pressurized gas, an order of bonding the top and edges of the display panel to form a three-dimensional curved surface with the cover can be precisely controlled to ensure exhaust and avoid the generation of bubbles.

### BRIEF DESCRIPTION OF THE DRAWINGS

### Description of the Drawings

In order to explain the embodiments or the technical solutions in the prior art more clearly, the following will briefly introduce the drawings that need to be used in the description of the embodiments or the prior art. Obviously, the drawings in the following description are only some embodiments of the invention. For those of ordinary skill in the art, other drawings can be obtained based on these drawings without creative work.

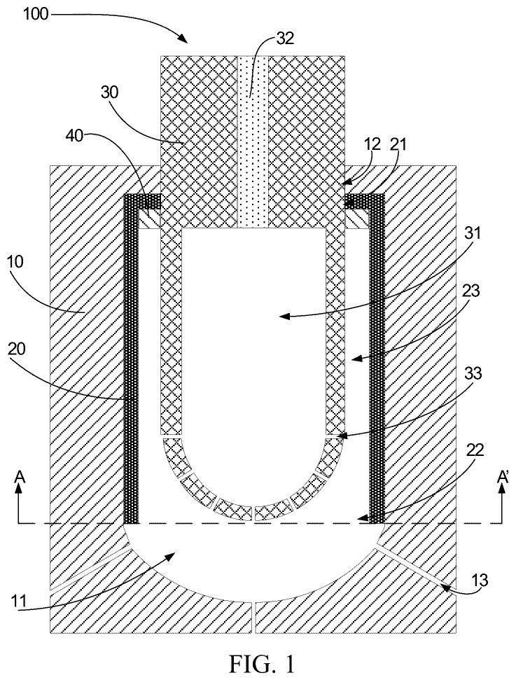

FIG. 1 is a schematic diagram of a planar structure of an attaching device provided by an embodiment of the present application.

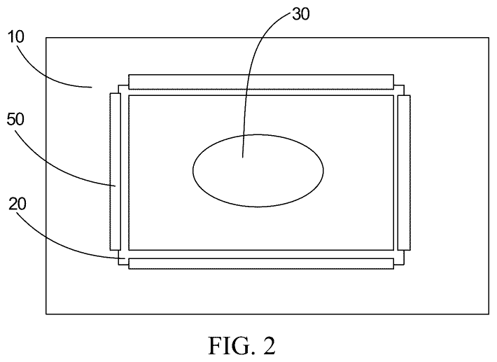

FIG. 2 is a schematic bottom view in FIG. 1 along a direction A-A′.

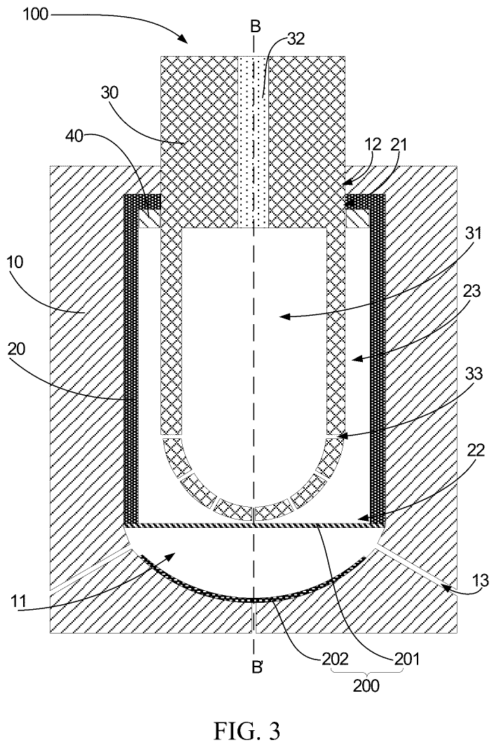

FIG. 3 is a schematic diagram of a planar structure in which a member to be attached is placed in an attaching device provided by an embodiment of the present application.

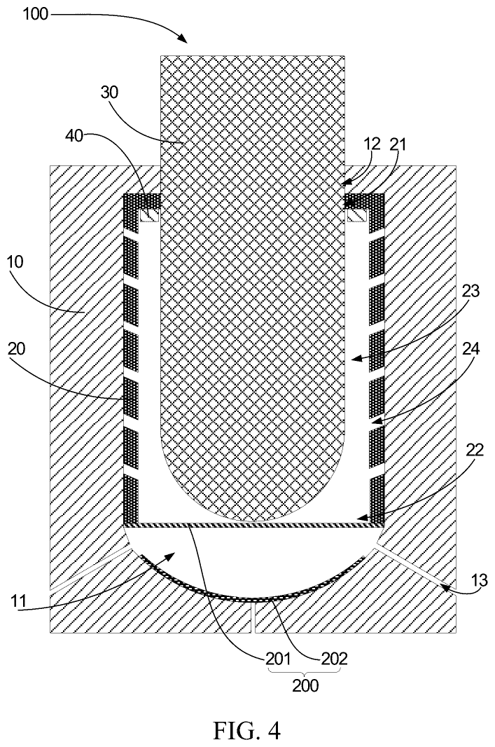

FIG. 4 is a schematic diagram of another planar structure of an attaching device provided by an embodiment of the present application.

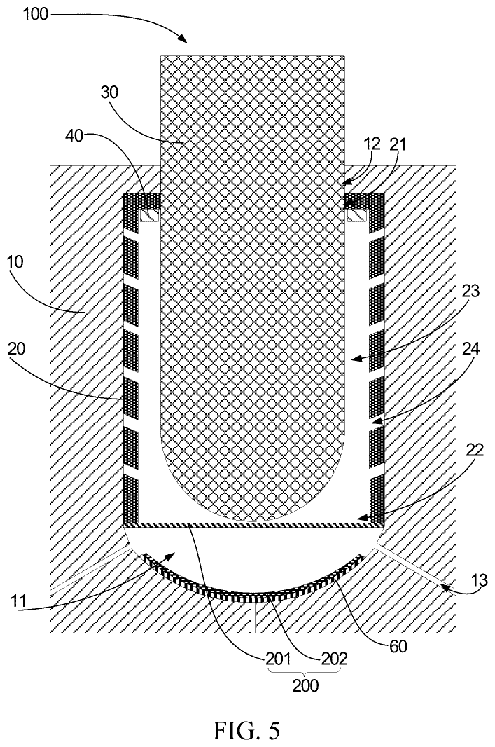

FIG. 5 is a schematic diagram of another planar structure of an attaching device provided by an embodiment of the present application.

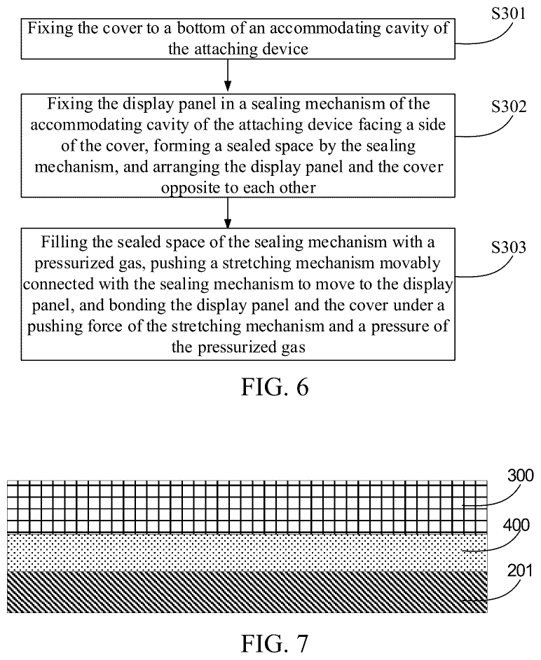

FIG. 6 is a schematic flowchart of a method for attaching a display cover provided by an embodiment of the present application.

FIG. 7 is a schematic diagram of a cross-sectional connection structure with a protective layer attached to a display panel provided by an embodiment of the present application.

### EMBODIMENTS OF INVENTION

### Detailed Description

The description of the following embodiments refers to the attached drawings to illustrate specific embodiments that can be implemented in the present application. The directional terms mentioned in this application, such as “up”, “down”, “front”, “back”, “left”, “right”, “inner”, “outer”, “side”, etc., are only directions for referring to the attached drawings. Therefore, the directional terms used are used to illustrate and understand the application, rather than to limit the application. In the figure, units with similar structures are indicated by the same reference numerals. In the drawings, the thickness of some layers and regions are exaggerated for clear understanding and ease of description. That is, the size and thickness of each component shown in the drawings are arbitrarily shown, but the application is not limited thereto.

Refer to FIG. 1 to FIG. 3 in conjunction, FIG. 1 is a schematic diagram of a planar structure of an attaching device provided by an embodiment of the present application, FIG. 2 is a schematic bottom view in FIG. 1 along a direction A-A′, and FIG. 3 is a schematic diagram of a planar structure in which a member to be attached is placed in an attaching device provided by an embodiment of the present application. An attaching device 100 includes a housing 10, a sealing mechanism 20, a stretching mechanism 30, and a heating mechanism 40. The housing 10 is formed with an accommodating cavity 11, and one side of the housing 10 has a first opening 12. The sealing mechanism 20 is disposed in the accommodating cavity 11 and has a second opening 21 and a third opening 22 opposite to the first opening 12. The stretching mechanism 30 passes through the first opening 12 and is slidably connected to the sealing mechanism 20 through the second opening 21. The heating mechanism 40 is fixed in a sealed space 23 of the sealing mechanism 20.

The attaching device 100 is used for attaching two structural members together, for example, it can be used for attaching a display cover. The display 200 includes a display panel 201 and a cover 202. The bonding of the display cover refers to bonding the display panel 201 and the cover 202 together. The display panel 201 includes OLED and micro-LED display panels and the like. In the case of an OLED display panel, the display panel 201 may include a base substrate, a driving circuit layer, a light-emitting function layer, an encapsulation layer, etc., which are sequentially stacked on the base substrate. In the case of a micro-LED display panel, the display panel 201 may include a base substrate, a driving circuit layer stacked on the base substrate, a micro-LED/mini-LED, an encapsulation layer, and the like.

The attaching device 100 of the present application is particularly suitable for a display 200 that is to form a three-dimensional curved surface. The three-dimensional curved display 200 refers to a three-dimensional curved display 200 by bonding the display panel 201 and the cover 202 with a three-dimensional curved surface together.

Specifically, the cover 202 is fixed to the bottom of the accommodating cavity 11. The display panel 201 is fixed to the side of the sealing mechanism 20 facing the bottom of the accommodating cavity 11. When the cover 202 is fixed to the bottom of the accommodating cavity 11, the display panel 201 is fixed to the side of the sealing mechanism 20 facing the cover. The side of the sealing mechanism 20 is the side close to the bottom of the accommodating cavity 11. Specifically, it is the third opening 22 of the sealing mechanism 20. The cover 202 includes a rigid substrate with high light transmittance, such as glass. One side of the cover 202 is provided with a transparent optical glue for bonding the display panel 201 and the cover 202. Therefore, the side of the cover 202 provided with the transparent optical glue faces the display panel 201.

The accommodating cavity 11 is a space enclosed by a plurality of side walls of the housing 10. One of the side walls of the housing 10 is provided with a first opening 12. Opposite the first opening 12 is the bottom of the accommodating cavity 11. The housing 10 may have a mold shape. The housing 10 can be opened and closed. When the housing 10 is opened, the display panel 201 and the cover 202 can be placed in the accommodating cavity 11 of the housing 10. After the display panel 201 and the cover 202 are placed, the housing 10 is closed, so that the sealing mechanism 20 forms a sealed space 23.

Optionally, the way of fixing the cover 202 to the bottom of the accommodating cavity 11 includes setting a stopper on the housing 10 at the bottom of the accommodating cavity 11. The stopper is located around the cover 202 to clamp the cover 202. Or the housing 10 at the bottom of the accommodating cavity 11 is sunk into a recessed platform. The cover 202 is placed in the recessed platform, and the cover 202 is adsorbed by a negative pressure. It can be understood that, in order to realize the display 200 with a three-dimensional curved surface, the cover 202 needs to have a formed three-dimensional curved surface. The formed three-dimensional curved surface on the cover 202 matches with the recessed platform on which the cover 202 is fixed in the attaching device 100. This enables the cover 202 to make good contact with the housing 10 at the bottom of the accommodating cavity 11 and ensures the accurate alignment of the display panel 201 and the cover 202.

Optionally, the way of fixing the display panel 201 to the third opening 22 of the sealing mechanism 20 includes arranging a clamping member 50 around the third opening 22 of the sealing mechanism 20. The clamping member 50 clamps the display panel 201 to maintain a stable state.

The second opening 21 of the sealing mechanism 20 is disposed opposite to the third opening 22, and the second opening 21 is smaller than the third opening 22. The stretching mechanism 30 passes through the first opening 12 of the housing 10 and is slidably connected to the second opening 21, so that part of the stretching mechanism 30 is located in the closed mechanism 20. After the display panel 201 is fixed to the scaling mechanism 20, the sealing mechanism 20 is made to form a sealed space 23. The heating mechanism 40 is arranged in the sealed space 23 of the sealing mechanism 20 and is used for heating the display panel 201 so that the display panel 201 can be stretched and formed more easily.

Optionally, the heating mechanism 40 may be fixed on the edge of the first opening 12 of the sealing mechanism 20 or on the side wall of the sealing mechanism 20 and other positions. The heating method of the heating mechanism 40 includes heating methods such as UV irradiation, infrared heating, resistance wire heating, microcrystalline heating plate, quartz tube and the like. In addition, the heating temperature of the heating mechanism 40 can be controlled between 70 degrees Celsius and 150 degrees Celsius to avoid exceeding the temperature resistance of the transistors and metal circuits in the display panel 201. The temperature control can be achieved by arranging a temperature sensor in the accommodating cavity 11 of the sealing mechanism 20 to precisely control the molding temperature.

The stretching mechanism 30 is slidably connected to the sealing mechanism 20 through the second opening 21, so that the stretching mechanism 30 can move axially in the accommodating cavity 11 of the housing 10. Specifically, the stretching mechanism 30 moves axially in the sealed space of the sealing mechanism 20. The axial movement can push the display panel 201 to deform in the direction of the cover 202, so that the display panel 201 and the cover 202 are attached to each other. Of course, to make the stretching mechanism 30 move axially, the stretching mechanism 30 can be driven by a power mechanism. The power mechanism may be connected to the end of the stretching mechanism 30 located outside the housing 10. The power mechanism includes a mechanism with power driving such as a stepping motor. By controlling the speed parameters of the power mechanism, the traveling speed of the stretching mechanism 30 can be precisely controlled. The speed parameter of the power mechanism is variable, so that the traveling speed of the stretching mechanism 30 is also variable. For example, the axial movement speed of the stretching mechanism 30 before contacting the display panel 201 is greater than the axial movement speed of the stretching mechanism 30 after contacting the display panel 201.

In order to prevent the display panel 201 and the cover 202 from generating bubbles and other defects during the bonding process, the stretching mechanism 30 may first seal the sealing mechanism 20 before pushing the display panel 201 to deform. The sealed space 23 is filled with pressurized gas, such as air, nitrogen, and the like. Optionally, the pressurized gas may enter the sealed space 23 of the sealing mechanism 20 through the stretching mechanism 30. Specifically, the stretching mechanism 30 includes a chamber 31, a first air inlet 32 located on one side of the chamber 31, and a first air outlet 33 located on the other side of the chamber 31. The first air outlet 33 is arranged close to the connecting end of the stretching mechanism 30 and the power mechanism. The first air outlets 33 are evenly dispersed on the side wall of the stretching mechanism 30. The chamber 31 passes through the sealed space 23 of the sealing mechanism 20 through the first air outlet 33. The pressurized gas enters the chamber 31 through the first air inlet 32 and enters the sealed space 23 of the sealing mechanism 20 through the first air outlet 33.

The display panel 201 deforms toward the cover 202 under a pushing force of the stretching mechanism 30 and the pressure of the pressurized gas. This makes the display panel 201 and the cover 202 adhere to each other. The end of the stretching mechanism 30 away from the power mechanism is a circular arc surface to avoid scratching the display panel 201. The center line B-B′ of the stretching mechanism 30 passes through the center point of the arc end surface of the stretching mechanism 30 and passes through the center point of the three-dimensional curved surface of the cover 202. In this way, the arc surface end of the stretching mechanism 30 can make the maximum deformation point of the display panel 201 coincide with the maximum deformation point of the cover 202. That is, the contact position of the display panel 201 and the stretching mechanism 30 is attached to the cover 202 first. Then, under the pressure of the pressurized gas, the display panel 201 gradually continues to deform around the stretching mechanism 30 and adheres to the cover 202. In order to prevent excessive pressure from damaging the display panel 201, the pressure range of the pressurized gas can be controlled between 0.5 Mpa and 4 Mpa. In order to precisely control the pressure in the sealed space 23, a pressure sensor can be provided in the sealed space.

In addition, in the process of attaching the display panel 201 and the cover 202, in order to discharge the gas between the display panel 201 and the cover 202 in time, the housing 10 is also provided with a second air outlet 13. The second air outlet 13 can discharge the gas between the display panel 201 and the cover 202, and the second air outlet 13 is not blocked by the cover 202. Of course, before the attaching device 100 is placed in the display panel 201 and the cover 202, the sealed space 23 of the sealing mechanism 20 is communicated with the outside through the second air outlet 13.

In this embodiment, the attaching device 100 can attach the display panel 201 and the cover 202 together to form the required three-dimensional curved display 200. The integration of the molding and bonding of the display 200 avoids problems such as poor bonding and wrinkles caused by the difference in curvature when the display panel 201 and the cover 202 are molded separately. Using the attaching device 100 of the present application does not require molding methods such as high temperature injection molding, high pressure extrusion, and stamping. This solves the problem that the current flexible OLED and flexible micro-LED displays have limited molding processes for realizing three-dimensional curved surfaces. Moreover, by controlling the timing of the axial pressing of the stretching mechanism 30 and the pressurized gas, the order of bonding the top and edges of the display panel 201 to form a three-dimensional curved surface with the cover 202 can be precisely controlled to ensure exhaust and avoid the generation of bubbles.

In an embodiment, please refer to FIG. 4, which is a schematic diagram of another planar structure of the attaching device provided by the embodiment of the application. The difference from the foregoing embodiment is that the pressurized gas does not enter the sealed space 23 of the sealing mechanism 20 through the stretching mechanism 30, but enters the sealing mechanism 20 through the sealing mechanism 20 itself. Specifically, the sealing mechanism 20 is provided with a second air inlet 24. The second air inlet 24 is located between the second opening 21 and the third opening 22. That is, the second air inlet 24 is provided on the side wall between the second opening 21 and the third opening 22 of the sealing mechanism 20. Further, distributed pipelines can be provided on the housing 10. The pressurized gas is filled in from a step-by-step pipeline on the housing 10 and enters the sealing mechanism 20 through the second air inlet 24 of the scaling mechanism 20. In this way, the purpose of inflation and pressurization can also be achieved. For other descriptions, please refer to the above-mentioned embodiment, which will not be repeated here.

In an embodiment, please refer to FIG. 5, which is a schematic diagram of another planar structure of the attaching device provided by the embodiment of the application. Different from the above-mentioned embodiment, the attaching device 100 further includes a lifting mechanism 60 located at the bottom of the accommodating cavity 11. The cover 202 is fixed on the lifting mechanism 60. The lifting mechanism 60 is used to push the cover 202 to move to the display panel 201. In this way, the stretching molding can be changed from the unidirectional movement of the stretching mechanism 30 to the coaxial movement molding of the stretching mechanism 30 and the cover 202 toward each other. Furthermore, the stroke length of the stretching mechanism 30 can be shortened, the stretching time of the stretching mechanism 30 can be shortened, and the efficiency of inflation and pressure can be improved. For other descriptions, please refer to the above-mentioned embodiment, which will not be repeated here.

Based on the same inventive concept, the present application also provides a method for attaching a display cover. The display 200 includes a display panel 201 and a cover 202. The display panel 201 and the cover 202 are attached by the attaching device 100 of one of the above-mentioned embodiments.

Specifically, please refer to FIG. 1 to FIG. 7 in combination. FIG. 6 is a schematic flowchart of a method for attaching a display cover according to an embodiment of the application. FIG. 7 is a schematic diagram of a cross-sectional connection structure with a protective layer attached to a display panel provided by an embodiment of the application. The attaching device 100 includes a housing 10, a sealing mechanism 20, and a stretching mechanism 30. The housing 10 is formed with an accommodating cavity 11, and one side of the housing 10 has a first opening 12. The sealing mechanism 20 is disposed in the accommodating cavity 11 and has a second opening 21 and a third opening 22 opposite to the first opening 12. The stretching mechanism 30 passes through the first opening 12 and is slidably connected to the sealing mechanism 20 through the second opening 21. The method for attaching the display cover includes the following steps:

S301: Fix the cover 202 to the bottom of the accommodating cavity 11 of the attaching device 100;

Specifically, the cover 202 includes a rigid substrate with high light transmittance, such as glass, and is formed into a three-dimensional curved surface. One side of the cover 202 is provided with a transparent optical glue for bonding the display panel 201 and the cover 202, such that the side of the cover 202 provided with the transparent optical glue faces the accommodating cavity 11.

Optionally, the way of fixing the cover 202 to the bottom of the accommodating cavity 11 includes setting a stopper on the housing 10 at the bottom of the accommodating cavity 11. The stopper is located around the cover 202 to clamp the cover 202. Or the housing 10 at the bottom of the accommodating cavity 11 is sunk into a recessed platform. The cover 202 is placed in the recessed platform, and the cover 202 is adsorbed by a negative pressure. The formed three-dimensional curved surface on the cover 202 matches with the recessed platform on which the cover 202 is fixed in the attaching device 100. This enables the cover 202 to make good contact with the housing 10 at the bottom of the accommodating cavity 11 and ensures the accurate alignment of the display panel 201 and the cover 202.

S302: Fix the sealing mechanism 20 of the display panel 201 in the accommodating cavity of the attaching device facing the side of the cover 202, so that the sealing mechanism 20 forms a sealed space 23, and the display panel 201 and the cover 202 are disposed opposite to each other;

Specifically, the edge of the third opening 22 of the sealing mechanism 20 is provided with a clamping member 50. The step of fixing the display panel 201 to the side of the sealing mechanism 20 facing the cover 202 includes fixing the display panel 201 to the side of the sealing mechanism 20 facing the cover 202 by the clamping member 50. That is, at the third opening 22 of the sealing mechanism 20. After the display panel 201 is fixed to the sealing mechanism 20, the sealing mechanism 20 is made to form a sealed space 23. The display panel 201 and the cover 202 are disposed opposite to the side where the transparent optical glue is disposed.

S303: Fill the sealed space 23 of the sealing mechanism 20 with pressurized gas, and push the stretching mechanism 30 movably connected with the sealing mechanism 20 to move toward the display panel 201, and under the pushing force of the stretching mechanism 30 and the pressure of the pressurized gas, the display panel 201 and the cover 202 are attached to each other.

Specifically, the attaching device 100 further includes a heating mechanism 40, the heating mechanism 40 is fixed in the sealed space 23 of the sealing mechanism 20; before filling the sealed space 23 of the sealing mechanism 20 with pressurized gas, the method for attaching the display cover includes the following steps:

The sealed space 23 of the sealing mechanism 20 and the display panel 201 are heated by the heating mechanism 40 fixed in the sealing mechanism 20 according to a preset temperature. The heating method of the heating mechanism 40 includes heating methods such as UV irradiation, infrared heating, resistance wire heating, microcrystalline heating plate, quartz tube and the like. In addition, the heating temperature of the heating mechanism 40 can be controlled between 70 degrees Celsius and 150 degrees Celsius. This avoids exceeding the temperature resistance of the transistors and metal circuits in the display panel 201. The temperature can be controlled by arranging a temperature sensor in the accommodating cavity 11 of the sealing mechanism 20 to precisely control the molding temperature.

Further, after the heating mechanism 40 is used to heat the display panel 201, the sealed space 23 of the sealing mechanism 20 is filled with pressurized gas, such as air, nitrogen, and the like. Optionally, the pressurized gas may enter the sealed space 23 of the sealing mechanism 20 through the stretching mechanism 30. Specifically, the stretching mechanism 30 includes a chamber 31, a first air inlet 32 located on one side of the chamber 31, and a first air outlet 33 located on the other side of the chamber 31. The first air outlet 33 is arranged close to the connecting end of the stretching mechanism 30 and the power mechanism. The first air outlets 33 are evenly dispersed on the side wall of the stretching mechanism 30. The chamber 31 passes through the sealed space 23 of the sealing mechanism 20 through the first air outlet 33. In this way, the pressurized gas is filled into the chamber 31 through the first air inlet 32, and the pressurized gas enters the sealed space 23 of the sealing mechanism 20 through the first air outlet 33.

Or, optionally, the pressurized gas enters the sealing mechanism 20 through the sealing mechanism 20 itself. Specifically, the sealing mechanism 20 is provided with a second air inlet 24. The second air inlet 24 is located between the second opening 21 and the third opening 22. That is, the second air inlet 24 is provided on the side wall between the second opening 21 and the third opening 22 of the sealing mechanism 20. Distributed pipelines can be provided on the housing 10. The pressurized gas is filled in from a step-by-step pipeline on the housing 10 and enters the sealing mechanism 20 through the second air inlet 24 of the sealing mechanism 20. In this way, the purpose of inflation and pressurization can also be achieved.

In order to avoid excessive pressure from damaging the display panel 201, the pressure range of the pressurized gas can be controlled between 0.5 Mpa and 4 Mpa.

After being filled with the pressurized gas, the stretching mechanism 30 is simultaneously pushed to move to the display panel 201. Under the action of the pushing force of the stretching mechanism 30 and the pressure of the pressurized gas, the display panel 201 is attached to the cover 202. Specifically, the end of the stretching mechanism 30 away from the power mechanism is an arc surface to avoid scratching the display panel 201. The arc surface end of the stretching mechanism 30 can make the maximum deformation point of the display panel 201 coincide with the maximum deformation point of the cover 202. That is, the contact position of the display panel 201 and the stretching mechanism 30 is attached to the cover 202 first. Then, under the pressure of the pressurized gas, the display panel 201 gradually continues to deform around the stretching mechanism 30 and adheres to the cover 202.

In addition, in the process of attaching the display panel 201 and the cover 202, in order to discharge the gas between the display panel 201 and the cover 202 in time, the housing 10 is also provided with a second air outlet 13. The second air outlet 13 can discharge the gas between the display panel 201 and the cover 202, and the second air outlet 13 is not blocked by the cover 202. Of course, before the attaching device 100 is placed in the display panel 201 and the cover 202, the sealed space 23 of the sealing mechanism 20 is communicated with the outside through the second air outlet 13.

In an embodiment, different from the method for attaching the display cover in the foregoing embodiment, the attaching device 100 further includes a lifting mechanism 60 located at the bottom of the accommodating cavity 11. The cover 202 is fixed on the lifting mechanism 60. Then the step of pushing the stretching mechanism 30 to move to the display panel 201 further includes the following.

The stretching mechanism 30 is pushed to move to the display panel 201, and the lifting mechanism 60 pushes the cover 202 to move to the display panel 201. In this way, the stretching molding can be changed from the unidirectional movement of the stretching mechanism 30 to the coaxial movement molding of the stretching mechanism 30 and the cover 202 toward each other. Furthermore, the stroke length of the stretching mechanism 30 can be shortened, the stretching time of the stretching mechanism 30 can be shortened, and the efficiency of inflation and pressure can be improved.

In an embodiment, different from the method for attaching the display cover in the foregoing embodiment, before the step of fixing the display panel 201 at the third opening 22 of the sealing mechanism 20, the method further includes the following.

A protective layer 300 is attached to one side of the display panel 201; the display panel 201 is fixed at the third opening 22 of the sealing mechanism 20, and the protective layer 300 faces the sealing mechanism 20.

Specifically, the material of the protective layer 300 includes non-crystallized polyethylene terephthalate (A-PET), polydimethylsiloxane (PDMS) and other materials with better elasticity. The protective layer 300 can be attached to the display panel 201 by a pressure sensitive adhesive (PSA) or other adhesive material layer 400 having adhesiveness. After the display panel 201 is attached to the cover 202, the protective layer 300 needs to be peeled off. The peeling method of peeling off the protective layer 300 includes other methods such as using a laser. Due to the existence of the protective layer 300, the pressure of the pressurized gas and the heating temperature of the heating mechanism 40 can be adjusted according to the temperature and pressure resistance of the protective layer 300 to better protect the display panel 201.

In addition, it should be noted that after the display panel 201 and the cover 202 are attached, the part of the display panel 201 clamped by the clamping member is not attached to the cover 202. The part that is not attached to the cover 202 needs to be removed.

According to the above embodiment:

In the attaching method for the display cover and the attaching device provided in the present application, the display panel is fixed to the sealing mechanism, and the cover is fixed to the bottom of the accommodating cavity of the housing. The heating mechanism is used to heat the display panel, and the pressurized gas is filled into the sealed space of the sealing mechanism. Further, the stretching mechanism pushes the display panel to deform. The display panel and the cover are bonded under the action of the stretching mechanism and the pressurized gas, so that molding and bonding of the display are integrated. This avoids problems such as poor fit and wrinkles caused by a difference in curvature when the display panel and the cover are formed separately. This solves the problem that current flexible OLED and flexible micro-LED displays have limited molding processes for realizing three-dimensional curved surfaces. Further, by controlling timing of an axial pressing of the stretching mechanism and the pressurized gas, an order of bonding the top and edges of the display panel to form a three-dimensional curved surface with the cover can be precisely controlled to ensure exhaust and avoid the generation of bubbles.

In the above-mentioned embodiments, the description of each embodiment has its own focus. For parts that are not described in detail in an embodiment, reference may be made to related descriptions of other embodiments.

The embodiments of the present application are described in detail above. Specific examples are used in this article to illustrate the principle and implementation of this application. The descriptions of the above embodiments are only used to help understand the technical solutions and core ideas of the present application. Those of ordinary skill in the art should understand that they can still modify the technical solutions described in the foregoing embodiments, or equivalently replace some of the technical features. However, these modifications or replacements do not cause the essence of the corresponding technical solutions to deviate from the scope of the technical solutions of the embodiments of the present application.

What is claimed is:

1. A method for attaching a display cover, wherein a display comprises a display panel and a cover, the display panel and the cover are attached by an attaching device, and the method for attaching the display cover comprises:
fixing the cover to a bottom of an accommodating cavity of the attaching device;
fixing the display panel in a sealing mechanism of the accommodating cavity of the attaching device facing a side of the cover, forming a sealed space by the sealing mechanism, and arranging the display panel and the cover opposite to each other;
filling the sealed space of the sealing mechanism with a pressurized gas, pushing a stretching mechanism movably connected with the sealing mechanism to move to the display panel, and bonding the display panel and the cover under a pushing force of the stretching mechanism and a pressure of the pressurized gas.

2. The method for attaching the display cover according to claim 1, wherein before filling the sealed space of the sealing mechanism with the pressurized gas, the method for attaching the display cover comprises following steps:
heating the sealed space of the sealing mechanism and the display panel at a preset temperature by a heating mechanism fixed in the sealing mechanism.

3. The method for attaching the display cover according to claim 2, wherein the preset temperature ranges from 70 degrees Celsius to 150 degrees Celsius.

4. The method for attaching the display cover according to claim 2, wherein a heating method of the heating mechanism comprises at least one heating method selected from a UV irradiation, an infrared heating, a resistance wire heating, a microcrystalline heating plate heating, and a quartz tube heating.

5. The method for attaching the display cover according to claim 1, wherein a step of filling the sealed space of the sealing mechanism with the pressurized gas comprises:
filling the pressurized gas into a chamber of the stretching mechanism through a first air inlet of the stretching mechanism located outside the sealing mechanism, and the pressurized gas entering the sealed space of the sealing mechanism through a first air outlet of the stretching mechanism located in the sealing mechanism.

6. The method for attaching the display cover according to claim 1, wherein a step of filling the sealed space of the sealing mechanism with the pressurized gas comprises:
filling the sealed space of the sealing mechanism with the pressurized gas through a second air inlet on the sealing mechanism.

7. The method for attaching the display cover according to claim 1, wherein a pressure of the pressurized gas ranges from 0.5 Mpa to 4 Mpa.

8. The method for attaching the display cover according to claim 1, wherein a step of fixing the display panel at a third opening of the sealing mechanism comprises:
fixing the display panel to a side of the sealing mechanism facing the cover through a clamping member on the sealing mechanism.

9. The method for attaching the display cover according to claim 1, wherein a step of pushing the stretching mechanism to move to the display panel further comprises:
pushing the stretching mechanism to move to the display panel and making a lifting mechanism at the bottom of the accommodating cavity push the cover to move to the display panel.

10. The method for attaching the display cover according to claim 1, wherein before fixing the display panel in the sealing mechanism of the accommodating cavity of the attaching device facing the side of the cover, the method further comprises:
attaching a protective layer to a side of the display panel;
fixing the display panel on a side of the sealing mechanism facing the cover, and the protective layer facing the sealing mechanism.

11. The method for attaching the display cover according to claim 10, further comprising peeling off the protective layer after bonding the display panel and the cover.

12. An attaching device, comprising:
a housing formed with an accommodating cavity, wherein a side of the housing has a first opening;
a sealing mechanism disposed in the accommodating cavity and having a second opening and a third opening opposite to the first opening;
a stretching mechanism passing through the first opening and being slidably connected to the sealing mechanism through the second opening.

13. The attaching device according to claim 12, further comprising a heating mechanism fixed in the sealed space of the sealing mechanism.

14. The attaching device according to claim 13, wherein the stretching mechanism comprises a chamber, a first air inlet on a side of the chamber, and a first air outlet on another side of the chamber, and the chamber passes through the sealed space of the sealing mechanism through the first air outlet.

15. The attaching device according to claim 14, wherein an end of the stretching mechanism located in the sealed space of the sealing mechanism is a circular arc surface.

16. The attaching device according to claim 13, wherein the sealing mechanism is provided with a second air inlet, and the second air inlet is located between the second opening and the third opening.

17. The attaching device according to claim 12, wherein the housing corresponding to the bottom of the accommodating cavity is provided with a second air outlet, and the sealed space of the sealing mechanism is communicated with an outside through the second air outlet.

18. The attaching device according to claim 12, further comprising a clamping member, the clamping member being disposed on an edge of the third opening of the sealing mechanism.

19. The attaching device according to claim 12, further comprising a lifting mechanism disposed at the bottom of the accommodating cavity.

20. The attaching device according to claim 12, wherein a size of the second opening is less than a size of the third opening.
